(19) United States
(12) Patent Application Publication
(10) Pub. No.: US 2014/0191243 A1
(43) Pub. Date: Jul. 10, 2014

(54) PATTERNED ARTICLES AND LIGHT EMITTING DEVICES THEREFROM

(71) Applicants: SINMAT, INC., Gainesville, FL (US); UNIVERSITY OF FLORIDA RESEARCH FOUNDATION, INC., Gainesville, FL (US)

(72) Inventors: RAJIV K. SINGH, NEWBERRY, FL (US); PURUSHOTTAM KUMAR, GAINESVILLE, FL (US); DEEPIKA SINGH, NEWBERRY, FL (US)

(73) Assignees: UNIVERSITY OF FLORIDA RESEARCH FOUNDATION, INC., Gainesville, FL (US); SINMAT, INC., Gainesville, FL (US)

(21) Appl. No.: 13/736,372

(22) Filed: Jan. 8, 2013

(51) Int. Cl. H01L 33/60; H01L 21/02; H01L 33/00; F21V 5/00; F21V 7/22

(52) U.S. Cl. CPC H01L 33/60; F21V 5/00; F21V 7/22; H01L 33/005; H01L 21/02518
USPC 257/76; 362/326; 362/341; 427/162; 216/24; 438/478

(57) ABSTRACT

A patterned article includes a substrate support having planar substrate surface portions including a substrate material having a substrate refractive index. A patterned surface is on the substrate support including a plurality of features lateral to the planar substrate surface portions protruding above a height of the planar substrate surface portions. At least a top surface of the plurality of features include an epi-blocking layer including at least one of (i) a non-single crystal material having a refractive index lower as compared to the substrate refractive index and (ii) a reflecting metal or a metal alloy (reflecting material). The epi-blocking layer is not on the planar substrate surface portions.

### FIELD

Disclosed embodiments relate to light emitting diodes (LEDs) on patterned articles including patterned substrates.

### BACKGROUND

Lighting consumes nearly 25% of the world's electricity and thus is one of the largest consumers of energy and contributors to greenhouse gas emissions. In the decade 2000 to 2010 significant advancements have been made to LED-based solid state lighting systems with luminous efficiency increasing from about 20 lm/watt to nearly 100 lm/watt. Further improvement in efficiency and reduction in manufacturing cost is essential to make white LEDs cost competitive with fluorescent and incandescent bulbs.

LEDs generally include three semiconductor layers on a substrate. Between p-type and n-type semiconductor layers, an active region is provided. When the LED is forward-biased (switched on), the active region emits light when electrons and holes recombine there. GaN-based LEDs are common LEDs. One type of LED is an organic LED (OLED) where the emissive layer is a film of an organic compound that emits light.

Efficiency of light emitting devices (e.g., LEDs, OLEDs) can be increased by enhancing the internal quantum efficiency, which represents the conversion efficiency of electrons to photons, by improving the light extraction efficiency or out-coupling efficiency. External efficiency of LEDs, OLEDs and other thin film light emitting devices is known to be limited by the out-coupling efficiency (or extraction efficiency). The high refractive indices of the active layer leads to total internal reflection (TIR) and waveguiding of a significant portion of the generated light. The higher the refractive index of the active layer the smaller the escape cone defined by the critical angle for TIR.

Out-coupling efficiency has been improved by the opening of higher number of the six escapes cones for each direction (lateral and vertical) by use of thick transparent substrates, shaping of LED chips, or by reducing wave-guiding through modification of various interfaces in the device. Interface modification induces photon randomization thereby giving multiple chances to photons to escape upon subsequent reflections. Photon randomization has been achieved by simple interface roughening, or by having regular patterned structures at various interfaces, such as Bragg gratings, photonic crystals, micro-rings, microlenses, micro-pyramids, and cones.

Sapphire substrates, or sapphire wafers, are now used by the majority of the world's LED manufacturers for the production of green, blue, and white LEDs. Patterned sapphire substrates (PSS) have been shown to substantially improve the efficiency of LED devices as compared to planar surfaced sapphire substrates, essentially because of two reasons. Firstly, PSS improves the quality of epi-layer (reduces defect density) which increases the internal quantum efficiency, and secondly it increases the light out-coupling efficiency by reducing TIR.

Two types of substrate patterns are typically used for forming an epitaxial light emitting stack, patterns with recessed features such as trenches or circular holes, and patterns with protruding features. The GaN epi-growth on substrate patterns with recessed features occurs via epitaxial lateral overgrowth (ELOG). On a substrate with protruding features GaN growth is known to preferentially takes place from the (0001) flat bottom growing laterally over the protruding features in a process known as facet-controlled epitaxial lateral overgrowth. Both of these substrate patterns generally provide a reduction in defect density in the epitaxial layers.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed embodiments include patterned articles comprising a substrate support having planar substrate surface portions including a substrate material having a substrate refractive index. A patterned top surface is on the substrate support including a plurality of features lateral to the planar substrate surface portions protruding above a height of the planar substrate surface portions. At least a top surface of the plurality of features include an epitaxial (epi)-blocking layer including at least one of (i) a non-single crystal material (amorphous or polycrystalline) having a refractive index lower as compared to the substrate refractive index and (ii) a reflecting metal or a metal alloy (hereafter “reflecting material”). The epi-blocking layer can include 2 or more layers of different materials, or can be a particle-based layer. The epi-blocking layer is not on the planar substrate surface portions. Disclosed embodiments also include light emitting diodes (LEDs) on disclosed patterned articles, and methods to form the same, including chemical mechanical polishing (CMP)-based methods.

### BRIEF DESCRIPTION OF THE DRAWINGS

FIG. 1A is a cross sectional depiction of a patterned article including a patterned top surface on a substrate support including planar substrate surface portions and a plurality of features lateral to and protruding relative to the planar substrate portions, wherein the top surface includes an epi-blocking layer including (i) a non-single crystal material having a refractive index lower as compared to the substrate refractive index or (ii) a reflecting material, according to an example embodiment.

FIG. 1B is a cross sectional depiction of a patterned article, where the substrate support has a patterned top surface which provides bottom portions for a plurality of features lateral to and protruding relative to planar substrate surface portions, and wherein an epi-blocking layer is on top of the bottom portions, according to an example embodiment.

FIG. 1C is a cross sectional depiction of a patterned article, wherein the article has a patterned top surface, wherein the substrate support provides bottom portions for the plurality of features as well as the planar substrate surface portions, and wherein the epi-blocking layer including multiple layers is on top of the bottom portions, according to an example embodiment.

FIG. 1D is a cross sectional depiction of a patterned article, wherein the substrate support has planar top surface portions throughout, and wherein a plurality of features protrude relative to the planar substrate surface consisting of an epi-blocking layer, according to an example embodiment.

FIG. 2A is a cross sectional depiction of an LED device comprising a disclosed patterned article having an epi-blocking layer and an epitaxial stack on the patterned article comprising a p-type layer, an n-type layer, and an active layer between the p-type layer and the n-type layer, wherein the epitaxial stack is epitaxially oriented with respect to the planar substrate surface portions, according to an example embodiment.

FIG. 2B is a cross sectional depiction of an LED device comprising a disclosed patterned article having an epi-blocking layer and an epitaxial stack on a patterned article comprising a p-type layer, an n-type layer, and an active layer between said p-type layer and the n-type layer, wherein the epitaxial stack is epitaxially oriented with respect to the planar substrate surface portions, according to another example embodiment.

FIG. 2C is a cross sectional depiction of an LED device comprising a disclosed patterned article having an epi-blocking layer and an epitaxial stack on the patterned article comprising a p-type layer, an n-type layer, and an active layer between said p-type layer and the n-type layer, wherein the epitaxial stack is epitaxially oriented with respect to the planar substrate surface portions, according to yet another example embodiment.

FIGS. 3A-D are successive cross sectional depiction showing progress for an example method of forming patterned articles, according to an example embodiment.

### DETAILED DESCRIPTION

Disclosed embodiments in this Disclosure are described with reference to the attached figures, wherein like reference numerals are used throughout the figures to designate similar or equivalent elements. The figures are not drawn to scale and they are provided merely to illustrate the disclosed embodiments. Several aspects are described below with reference to example applications for illustration. It should be understood that numerous specific details, relationships, and methods are set forth to provide a full understanding of the disclosed embodiments. One having ordinary skill in the relevant art, however, will readily recognize that the subject matter disclosed herein can be practiced without one or more of the specific details or with other methods. In other instances, well-known structures or operations are not shown in detail to avoid obscuring structures or operations that are not well-known. This Disclosure is not limited by the illustrated ordering of acts or events, as some acts may occur in different orders and/or concurrently with other acts or events. Furthermore, not all illustrated acts or events are required to implement a methodology in accordance with this Disclosure.

Notwithstanding that the numerical ranges and parameters setting forth the broad scope of this Disclosure are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

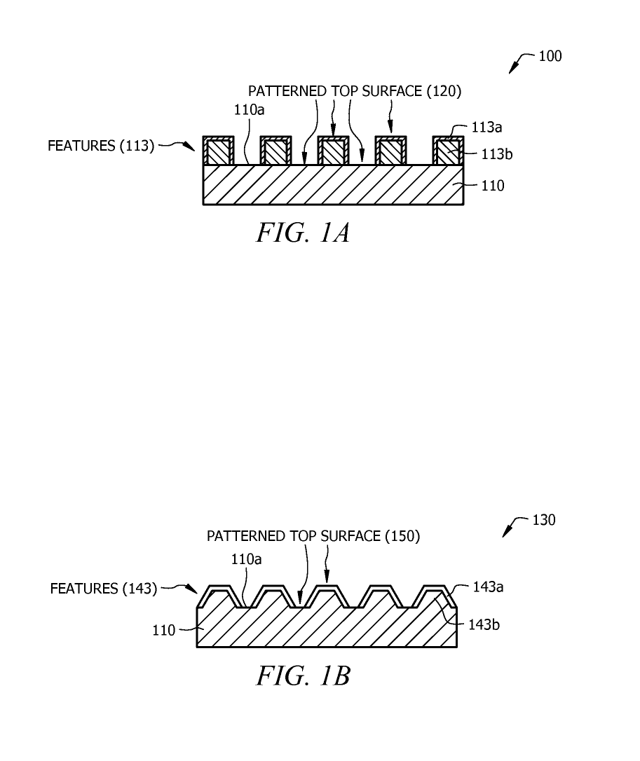

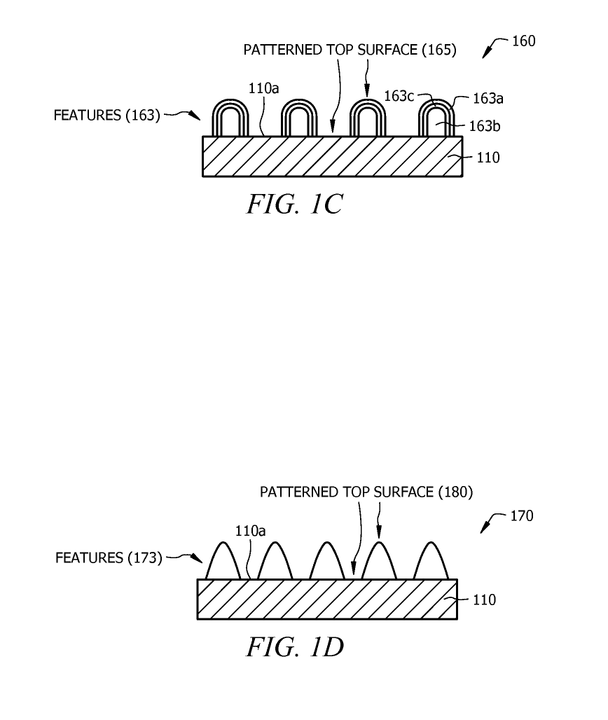

Disclosed embodiments include patterned articles, LEDs comprising disclosed patterned articles, and methods for forming LEDs on disclosed patterned articles. FIG. 1A is a cross sectional depiction of a patterned article 100, according to an example embodiment. The patterned article 100 comprises a substrate support 110 having planar substrate surface portions 110a including a substrate material having a substrate refractive index. The material for the substrate support 110 can comprise a variety of crystalline materials such as sapphire, silicon carbide, gallium nitride and silicon.

Patterned article 100 includes a patterned top surface 120. The patterned top surface 120 includes the planar substrate surface portions 110a and a plurality of features 113 lateral to and protruding from the planar substrate surface portions 110a. Although the shape of the features 113 is shown as being rectangular having vertical sidewalls, disclosed features may have non-vertical side walls, including curved sidewalls to provide feature shapes such as conical or hemispherical. A typical height range for the plurality of features 113 is from 0.1 μm to 5 μm. The bottom diameter of the features 113 can vary from 0.5 μm to 20 μm, whereas the distance between centers of the features 113 (feature pitch) can vary from 1 μm to 20 μm.

At least a top surface of the plurality of features 113 includes an epi-blocking layer 113a on a bottom portion 113b of the feature. The epi-blocking layer 113a comprises (i) a non-single crystal (amorphous or polycrystalline) material having a refractive index lower as compared to the refractive index of the substrate support (substrate refractive index) and/or (ii) a reflecting metal or a metal alloy (reflecting material). The epi-blocking layer 113a is not on the planar substrate surface portions 110a. The thickness of the epi-blocking layer 113a is generally between 100 Å and 5 μm. The epi-blocking layer 113a may cover between 10% and 100% of the surface area of the bottom portion 113b of the features.

The epi-blocking layer 113a can be a single layer, or as shown in FIG. 1C described below, can include multiple layers. The refractive index of the epi-blocking layer 113a is generally at least 0.1 lower than the refractive index of the substrate support 110. The epi-blocking layer 113a can also comprise a particle-based layer. In a particle-based layer, a monolayer or multiple layers of particles (nano to micron in size) is arranged in a close pack arrangement covering the top and sidewall surfaces (e.g., patterned curvilinear surfaces) of the features 113. The coverage can be between 10-100% of the bottom portion 113b of the features. The particles of the monolayer comprise a material having a refractive index lower than that of the substrate support 110. Examples of dielectric epi-blocking layer materials include silicon oxide, silicon nitride, an aluminate, and non-silicon oxides such as calcium fluoride (CaF₂), and magnesium fluoride (MgF₂).

Patterned article 100 (and patterned articles 130 and 160 described below relative to FIGS. 1B and 1C) can be used to form an LED by depositing an epitaxial stack thereon comprising a p-type layer, an n-type layer, and an active layer between the p-type layer and n-type layer. The epitaxial stack is epitaxially oriented with respect to only the planar substrate surface portions 110a.

The refractive index of the non-single crystal material which may be referred to as a “capping layer” can vary from 1 (essentially that of air, which is a minimum value) to less than that of the material of the substrate support 110 (e.g., about 1.7 for sapphire, about 2.4 to 2.6 for silicon carbide, and about 2.4 for gallium nitride). The refractive index of a material is known to vary with the wavelength of light. The refractive index values provided are generally quoted herein in the visible range. Light extraction performance generally improves the lower the refractive index is for the capping layer.

Although not shown in FIG. 1A, a layer of reflecting material may replace or be in addition to (below/under) the non-single crystal material/capping layer in the epi-blocking layer. The reflecting material can comprise Ta in one embodiment. However, the reflecting material can also comprise other metals such as Cr, Au, Ag, as well as various metal alloys. The reflecting material can comprise of materials with reflectivity>20% in the 400 to 700 nm wavelength range, such as TaN, and other nitride, carbides. In one embodiment, the features 113 include both the non-single crystal material and reflecting material, where the reflecting material is generally below the non-single crystal material/capping layer.

FIG. 1B is a cross sectional depiction of a patterned article 130, where the article has a patterned top surface 150, and where the substrate support 110 provides bottom portions 143b for the plurality of features 143 as well as the planar substrate surface portions 110a. An epi-blocking layer 143a is on top of the bottom portions 143b.

FIG. 1C is a cross sectional depiction of a patterned article 160, where the article has a patterned top surface 165, and where the substrate support 110 provides bottom portions 163b for the plurality of features 163 as well as the planar substrate surface portions 110a. An epi-blocking layer including layers 163a on 163c is on top of the bottom portions 163b. Layers 163a and 163c can comprise different low refractive index non-single crystal materials, such as silicon oxide on silicon nitride in one particular embodiment.

FIG. 1D is a cross sectional depiction of a patterned article 170 including a patterned top surface 180, wherein the substrate support 110 has planar top surface portions 110a throughout, and wherein the plurality of features 173 consist of an epi-blocking non-single crystal material. This embodiment demonstrates in one embodiment the features can consist of the non-single crystal material entirely in the form of a patterned thin film which provides the patterned top surface 180. Although not shown, as noted above, the features 173 may consist of a reflecting material as described above.

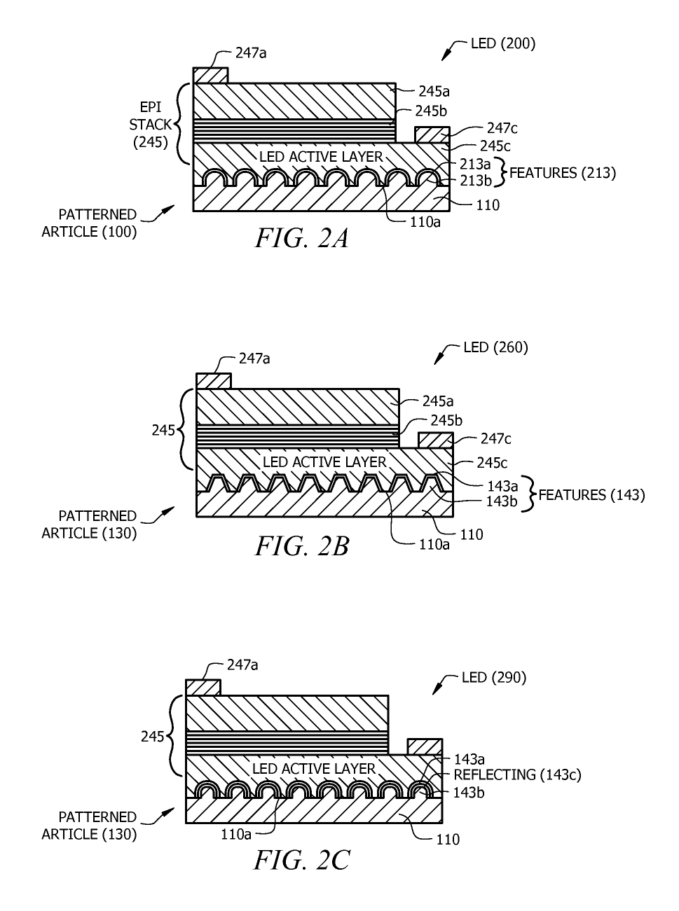

FIG. 2A is a cross sectional depiction of an LED device 200 comprising a disclosed patterned article 100′ analogous to patterned article 100 shown in FIG. 1A having features 213 including an epi-blocking layer 213a on bottom portions 213b provided by the substrate support 110, according to an example embodiment. An epitaxial stack 245 is on the patterned article 100′ comprising a p-type layer 245a, an n-type layer 245c, and an active layer 245b between the p-type layer and the-type layer. The epitaxial stack 245 is epitaxially oriented with respect to only the planar substrate surface portions 110a. Metal contacts 247a and 247c are provided to provide a low resistance ohmic contact for both the p-type layer 245a and the n-type layer 245c, respectively.

FIG. 2B is a cross sectional depiction of an LED device 260 comprising the disclosed patterned article 130 shown in FIG. 1B having features 143 comprising an epi-blocking layer 143a on bottom portions 143b provided by the substrate support 110, and an epitaxial stack 245 on the patterned article 130, according to another example embodiment. Epitaxial stack 245 comprises a p-type layer 245a, an n-type layer 245c, and an active layer 245b between the p-type layer and the n-type layer, wherein the epitaxial stack 245 is epitaxially oriented with respect to only the planar substrate surface portions 110a.

FIG. 2C is a cross sectional depiction of an LED device 290 comprising a disclosed patterned article 130′ analogous to the pattered article 130 shown in FIG. 1B, except having an additional reflecting layer 143c under the epi-blocking layer 143a, where the epi-blocking layer comprising a capping layer. An epitaxial stack 245 on the patterned article 130′ comprises a p-type layer 245a, an n-type layer 245c, and an active layer 245b between the p-type layer 245a and the n-type layer 245c. The epitaxial stack 245 is epitaxially oriented with respect to only the planar substrate surface portions 110a.

Disclosed embodiments include methods of forming patterned articles. The methods generally include providing a substrate support having planar substrate surface portions 110a comprising a substrate material having a substrate refractive index. As noted above, the substrate material may comprise crystalline materials, such as sapphire, silicon carbide, gallium nitride and silicon. An epi-blocking layer is deposited on the substrate support including (i) a non-single crystal material having a refractive index lower as compared to said the substrate refractive index or (ii) a reflecting metal or a metal alloy (reflecting material), and where the epi-blocking layer is not on the planar substrate surface portions. The epi blocking layer is patterned to form a patterned top surface on the substrate support including a plurality of features lateral to the planar substrate surface portions protruding above the planar substrate surface portions. At least a top surface of the plurality of features include the non-single crystal material or reflecting material, and the dielectric material and reflecting material (if present) are not on the planar substrate surface portions.

The substrate support can have a planar top surface throughout (see FIG. 1C) wherein plurality of features can consist of a material having a refractive index lower as compared to the refractive index of the substrate. The whole pattern can thus be of a low refractive index material such as silica, porous silica, other oxide, nitride, or silicate. For example, in one particular embodiment a silica layer 1 μm to 5 μm thick can be deposited and patterned instead of patterning the material of the substrate support 110.

In another embodiment the method can further comprise before the depositing and patterning, forming a masking layer on the substrate material, wherein the masking layer exposes a part (5-80%) of a top surface of the substrate material. At least one of a wet etch and a dry etch process can then be performed to remove an exposed part of the top surface of the substrate material to form a patterned substrate surface including planar substrate surface portions and features lateral to the planar substrate surface portions. A sacrificial layer can then be deposited on the patterned substrate surface.

Chemical mechanical polishing (CMP) can then be used for selectively removing the sacrificial layer from raised portions of the plurality of features while preserving the sacrificial layer over the planar substrate surface portions. CMP can alone thus create a recessed sacrificial layer. In this embodiment the polishing condition for CMP can be selected such that CMP polishes only the sacrificial layer and not the substrate. The recessed sacrificial layer can also be created by wet/dry etching depending on the sacrificial layer. Dry etching technique, such as reactive ion etching (RIE), can partially or fully etch the sacrificial layer from the top of the patterned area. Etching after CMP is not necessary, but can be included. The sacrificial layer can comprise either an organic or an inorganic film, such as a photoresist, a polymer, or various oxides, such as silica.

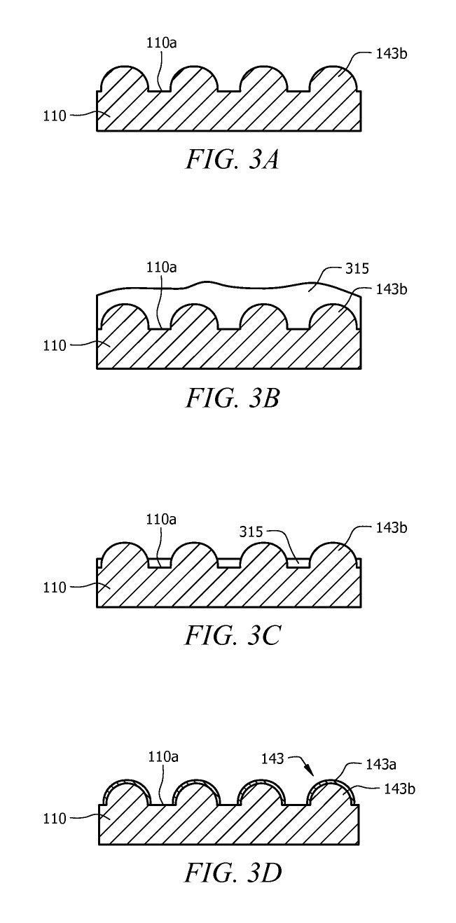

FIGS. 3A-D are successive cross sectional depictions showing progress for an example method of forming patterned articles, according to an example embodiment. The method described below results in formation of patterned article 130 shown in FIG. 1B. FIG. 3A shows a cross sectional view of a conventional wet and/or dry etch derived patterned substrate including planar substrate surface portions 110a and bottom portions 143b for features positioned lateral to the planar substrate surface portions 110a. The pattern shape shown in FIG. 3A is arbitrary and can be a variety of different shapes (e.g., conical and hemispherical).

FIG. 3B is a cross sectional view of a sacrificial layer 315 on the patterned substrate. FIG. 3C is a cross sectional view following removal of the sacrificial layer 315 to expose the bottom portions 143b of the patterned substrate which provide the patterned areas. As described above, CMP may be used for the selective removal of the sacrificial layer 315. Alternatively, dry and/or wet etching can also be used to selectively remove the sacrificial layer 315 from the patterned areas. FIG. 3D is a cross sectional view after deposition of an epi-blocking layer 143a and removal of the sacrificial layer 315 from the planar substrate surface portions 110a.

Disclosed patterned articles provide high efficiency light sources due to enhanced light extraction and improved epi-growth. As disclosed above, patterned articles can be fabricated by inserting an epi-blocking layer comprising a low refractive index and/or metallic reflective capping film layer on substrates including traditional patterned sapphire substrates (PSS), which is expected to result in up to about a 20% enhancement in light extraction efficiency. In the case of disclosed curvilinear layers, such curvilinear layers are expected to significantly enhance the random reflectivity of the surface, thereby increasing the light extraction efficiency for light emitting devices.

Disclosed patterned articles are significantly different structurally as compared to conventional PSS structures which only include high refractive index sapphire based features. It should be noted that even though >30% of worldwide high brightness LED production is generally based on use of standard PSS substrates, the use of capping low refractive index layers as described herein is not believed to have been disclosed before this disclosure. Significant advantages of disclosed patterned articles include (i) high efficiency and (ii) improved epi-growth (i.e., lower defect density) as compared to conventional dry/wet-etched PSS.

Significant advantages of the disclosed patterned articles are provided by introduction of a low refractive index non-single crystal layer (e.g., SiO₂) on a curvilinear surface substrate surface (with or without a reflecting material layer thereunder) can lead to reflection of a higher percentage of generated photons towards the emitting top surface of the light source instead of travelling in the substrate. Since the low refractive index non-single crystal layer/film will generally cover >70% of the substrate surface, and >90% in some embodiments, most of the photons generated will be reflected randomly at this interface. Thus, higher random reflection from a non-absorbing curved surface will lead to a significant increase in extraction efficiency.

Disclosed embodiments also provide for improved GaN epi-growth. GaN does not nucleate on disclosed epi-blocking layers (e.g., an amorphous SiO₂ film), which can cap the patterned area of the substrate. As noted above, disclosed patterned articles can have <10% of pristine substrate (e.g., sapphire) surface for GaN nucleation and growth using the epitaxial lateral overgrowth technique. Since >70%, such as >90% of the area of the substrate will have low defect density laterally grown GaN, disclosed methods lead to a significant reduction in defect density. In conventional wet etched PSS with trapezoidal shape, there are two (0001) oriented crystal substrate surfaces for GaN growth. Disclosed methods can cover one of these surfaces, such as with silica thus enabling GaN growth from only one pristine area of the substrate.

While various disclosed embodiments have been described above, it should be understood that they have been presented by way of example only, and not limitation. Numerous changes to the subject matter disclosed herein can be made in accordance with this Disclosure without departing from the spirit or scope of this Disclosure. In addition, while a particular feature may have been disclosed with respect to only one of several implementations, such feature may be combined with one or more other features of the other implementations as may be desired and advantageous for any given or particular application.

Thus, the breadth and scope of the subject matter provided in this Disclosure should not be limited by any of the above explicitly described embodiments. Rather, the scope of this Disclosure should be defined in accordance with the following claims and their equivalents.

The terminology used herein is for the purpose of describing particular embodiments only and is not intended to be limiting. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which embodiments of the invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

We claim:

1. A light emitting diode (LED) device, comprising:
a patterned article, comprising:
a substrate support including planar substrate surface portions comprising a substrate material having a substrate refractive index;
a patterned top surface on said substrate support including a plurality of features lateral to said planar substrate surface portions protruding above a height of said planar substrate surface portions,
wherein at least a top surface of said plurality of features include an epi-blocking layer including an (i) a non-single crystal material having a refractive index lower as compared to said substrate refractive index or (ii) a reflecting metal or a metal alloy material (reflecting material), and wherein said epi-blocking layer is not on said planar substrate surface portions, and
an epitaxial stack on said patterned article comprising a p-type layer, an n-type layer, and an active layer between said p-type layer and said n-type layer, wherein said epitaxial stack is epitaxially oriented with respect to said planar substrate surface portions.

2. The LED device of claim 1, wherein said substrate support has a patterned surface which further provides bottom portions for said plurality of features, and wherein said non-single crystal material or said reflecting material is on top of said bottom portions.

3. The LED device of claim 1, wherein said substrate support has a planar top surface throughout, and wherein said plurality of features consist of said non-single crystal material.

4. The LED device of claim 1, wherein said substrate material comprises sapphire, silicon carbide, gallium nitride, or silicon.

5. The LED device of claim 1, wherein said non-single crystal material comprises silicon oxide, silicon nitride, an aluminate, calcium fluoride, or magnesium fluoride.

6. The LED device of claim 1, wherein said p-type layer, said n-type layer, and said active layer all comprise III-V materials.

7. The LED device of claim 6, wherein said III-V materials all comprise GaN.

8. The LED device of claim 1, wherein said plurality of features include both said non-single crystal material and said reflecting material, wherein said reflecting material is below said non-single crystal material.

9. The LED device of claim 1, wherein a thickness of said epi-blocking layer is from 10 nm to 1,000 nm.

10. A patterned article, comprising:
a substrate support including planar substrate surface portions comprising a substrate material having a substrate refractive index;
a patterned top surface on said substrate support including a plurality of features lateral to said planar substrate surface portions protruding above a height of said planar substrate surface portions,
wherein at least a top surface of said plurality of features include an epi-blocking layer including a (i) non-single crystal material having a refractive index lower as compared to said substrate refractive index or (ii) a reflecting metal or a metal alloy (reflecting material), and wherein said epi-blocking layer is not on said planar substrate surface portions.

11. The patterned article of claim 10, wherein said substrate support has a patterned surface which provides bottom portions for said plurality of features, wherein said non-single crystal material or said reflecting material is on top of said bottom portions.

12. The patterned article of claim 10, wherein said substrate support has said planar substrate surface portions throughout, and wherein said plurality of features consist of said non-single crystal material or said reflecting material.

13. The patterned article of claim 10, wherein said substrate material comprises sapphire, silicon carbide, gallium nitride, or silicon.

14. The patterned article of claim 10, wherein said non-single crystal material comprises silicon oxide, silicon nitride, an aluminate, calcium fluoride, or magnesium fluoride.

15. The patterned article of claim 10, wherein said plurality of features include both said non-single crystal material and said reflecting material, and wherein said reflecting material is below said non-single crystal material.

16. A method of forming a patterned article, comprising:
providing a substrate support including planar substrate surface portions comprising a substrate material having a substrate refractive index;
depositing an epi-blocking layer including at least one of (i) a non-single crystal material having a refractive index lower as compared to said substrate refractive index and (ii) a reflecting metal or a metal alloy (reflecting material) on said substrate support, and
patterning said epi-blocking layer to form a patterned top surface on said substrate support including a plurality of features lateral to said planar substrate surface portions and protruding above said planar substrate surface portions, wherein at least a top surface of said plurality of features include said epi-blocking layer, and wherein said epi-blocking layer is not on said planar substrate surface portions.

17. The method of claim 16, wherein said substrate support has a planar top surface throughout, and wherein said plurality of features consist of said non-single crystal material or said reflecting material.

18. The method of claim 16, further comprising before said depositing and patterning:
forming a masking layer on said substrate support, wherein said masking layer exposes a portion of a top surface of said substrate support;
performing at least one of a wet etch and a dry etch process to remove an exposed part of said top surface of said substrate support to form a patterned substrate including said planar substrate surface portions and bottom feature portions for said plurality of features lateral to said planar substrate surface portions;
depositing a sacrificial layer after said performing, and
chemical mechanical polishing (CMP) or dry etching for selectively removing said sacrificial layer from raised portions of said plurality of features while preserving said sacrificial layer over said planar substrate surface portions.

19. The method of claim 16, wherein said substrate material comprises sapphire, silicon carbide, gallium nitride, or silicon.

20. The method of claim 16, further comprising forming an epitaxial stack on said patterned article comprising a p-type layer, an n-type layer, and an active layer between said p-type layer and said n-type layer, wherein said epitaxial stack is epitaxially oriented with respect to said planar substrate surface portions.
